(19) United States
(12) Patent Application Publication
(10) Pub. No.: US 2026/0206237 A1
(43) Pub. Date: Jul. 16, 2026

(54) SEMICONDUCTOR DEVICE AND METHOD OF MANUFACTURING SEMICONDUCTOR DEVICE

(71) Applicant: SK hynix Inc., Icheon-si (KR)

(72) Inventor: Nam Kyun Park, Icheon-si (KR)

(21) Appl. No.: 19/197,174

(22) Filed: May 2, 2025

(30) Foreign Application Priority Data
Jan. 15, 2025 (KR) 10-2025-0006326

(51) Int. Cl. H10B 63/00

(52) U.S. Cl. CPC H10B 63/80

(57) ABSTRACT

A semiconductor device includes first row lines extending in a first direction, common column lines located on the first row lines and extending in a second direction that crosses the first direction, second row lines located on the common column lines and extending in the first direction, first memory cells located between the first row lines and the common column lines, respectively, second memory cells located between the common column lines and the second row lines, respectively, second liner patterns each covering at least a sidewall of each of the first memory cells neighboring in the first direction, and third liner patterns each covering at least a sidewall of each of the second memory cells neighboring in the first direction and extending over a corresponding one of the second liner patterns.

### CROSS-REFERENCE TO RELATED APPLICATION

This application claims priority under 35 U.S.C. §119 to Korean Patent Application No. 10-2025-0006326 filed on January 15, 2025, which is incorporated herein by reference in its entirety.

### BACKGROUND

### 1. Technical Field

The present disclosure relates to an electronic device and a method of manufacturing the electronic device, and more particularly, to a semiconductor device and a method of manufacturing the semiconductor device.

### 2. Related Art

An integration degree of a semiconductor device is mainly determined by an area occupied by a unit memory cell. Recently, as improvement in an integration degree of a semiconductor device in which a memory cell is formed as a single layer on a substrate reaches a limit, a three-dimensional semiconductor device in which memory cells are stacked on a substrate is being proposed. In addition, various structures and manufacturing methods are being developed in order to improve operation reliability of the semiconductor device.

### SUMMARY

According to an embodiment of the present disclosure, a semiconductor device comprising: first row lines extending in a first direction; common column lines located on the first row lines and extending in a second direction that crosses the first direction; second row lines located on the common column lines and extending in the first direction; first memory cells located between the first row lines and the common column lines, respectively; second memory cells located between the common column lines and the second row lines, respectively; second liner patterns each covering at least a sidewall of each of the first memory cells neighboring in the first direction; and third liner patterns each covering at least a sidewall of each of the second memory cells neighboring in the first direction and extending over a corresponding one of the second liner patterns.

According to an embodiment of the present disclosure, a semiconductor device comprising: first row lines extending in a first direction; common column lines located on the first row lines and extending in a second direction that crosses the first direction; second row lines located on the common column lines and extending in the first direction; first memory cells located between the first row lines and the common column lines, respectively; second memory cells located between the common column lines and the second row lines, respectively; second gap fill patterns located between the first memory cells neighboring in the first direction; and third gap fill patterns located between the second memory cells neighboring in the first direction and extending between the first memory cells.

According to an embodiment of the present disclosure, a method of manufacturing a semiconductor device, the method comprising: forming first memory cells arranged in a first direction and a second direction that crosses the first direction; forming second liner patterns on the first memory cells; forming second gap fill patterns on the second liner patterns; forming second memory lines that extend in the second direction on the first memory cells; forming trenches exposing the second liner patterns by etching the second gap fill patterns; forming a third liner layer that extends into the trenches and over at least a sidewall of each of the second memory lines neighboring in the first direction; and forming a third gap fill layer in the trenches.

### BRIEF DESCRIPTION OF THE DRAWINGS

FIGS. 1A to 1C are drawings illustrating a semiconductor device according to an embodiment of the present disclosure.

FIGS. 2A, 2B, 3A, 3B, 4A, 4B, 5A, 5B, 6A, 6B, 7A, 7B, and 8A to 8C are drawings illustrating a method of manufacturing a semiconductor device according to an embodiment of the present disclosure.

### DETAILED DESCRIPTION

An embodiment of the present disclosure provides a semiconductor device and a method of manufacturing the semiconductor device having a stable structure and an improved characteristic.

According to the present technology, a semiconductor device having a stable structure and improved reliability may be provided. Hereinafter, embodiments according to the technical spirit of the present disclosure are described with reference to the accompanying drawings. Throughout the specification and claims, a list of items prefaced by a phrase such as "at least one of," "one or more of," or "one or both of" indicates an inclusive list. For example, a list of "at least one of A or B" and a list of "one or both of A and B" each indicate A, or B, or AB (i.e., A and B). Moreover, a first element "on" a second element indicates that the first element can be "directly on" the second element, or that at least one intervening element can be interposed between the first and second elements.

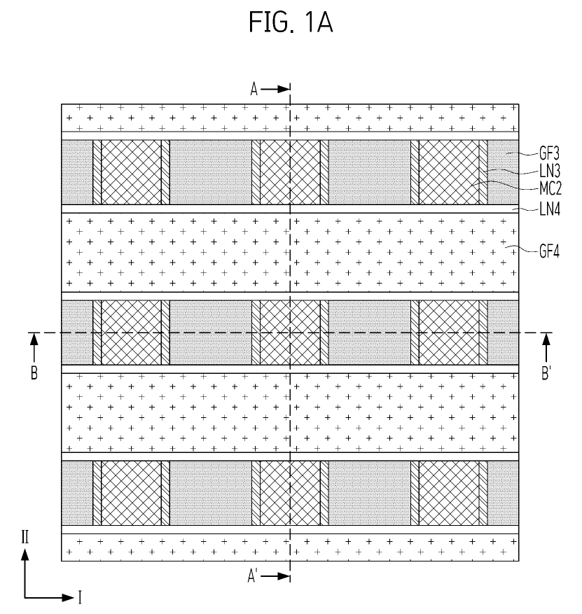

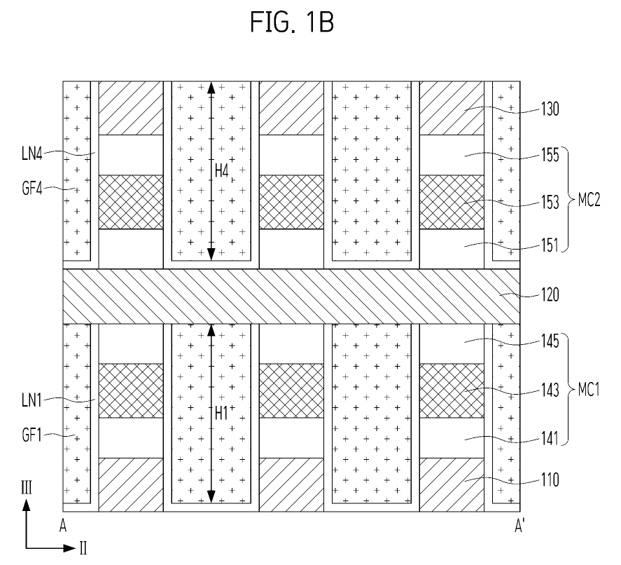

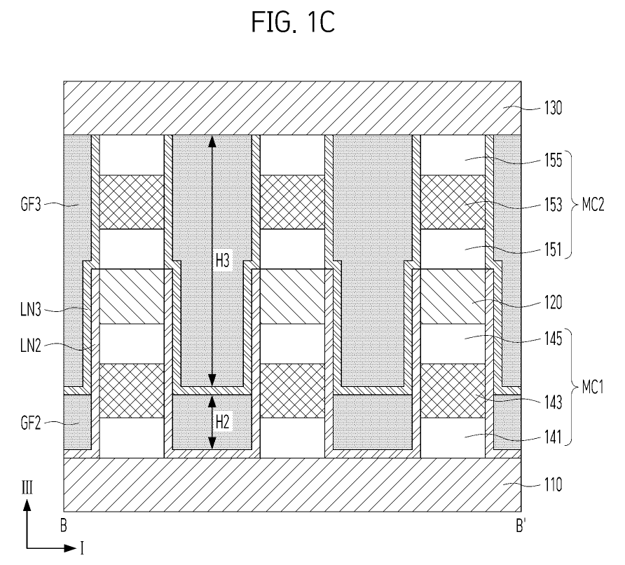

FIGS. 1A to 1C are drawings illustrating a semiconductor device according to an embodiment of the present disclosure. FIG. 1A is a plan view, FIG. 1B is a cross-sectional view taken along line A-A' of FIG. 1A, and FIG. 1C is a cross-sectional view taken along line B-B' of FIG. 1A.

Referring to FIGS. 1A to 1C, the semiconductor device may include first row lines 110, second row lines 130, common column lines 120, second row lines 130, first memory cells MC1, second memory cells MC2, first liner patterns LN1, second liner patterns LN2, third liner patterns LN3, fourth liner patterns LN4, first gap fill patterns GF1, second gap fill patterns GF2, third gap fill patterns GF3, and fourth gap fill patterns GF4.

The first row lines 110 may extend in a first direction I. The common column lines 120 may cross the first row lines 110, and may be located on the first row lines 110. The common column lines 120 may extend in a second direction II crossing the first direction I. The second row lines 130 may extend in the first direction I. The second row lines 130 may be located on the common column lines 120. As an example, the first and second row lines 110 and 130 may be word lines, and the common column lines 120 may be bit lines. As another example, the first and second row lines 110 and 130 may be bit lines, and the common column lines 120 may be word lines. Here, the first and second row lines 110 and 130 and the common column lines 120 may include a conductive material such as tungsten.

The first memory cells MC1 may be located between the first row lines 110 and the common column lines 120, respectively. The second memory cells MC2 may be located between the common column lines 120 and the second row lines 130, respectively. Each of the first memory cells MC1 may include a first lower electrode pattern 141 on a corresponding (e.g., coupled) one of the first row lines 110, a first variable resistance pattern 143, and a first upper electrode pattern 145. Each of the second memory cells MC2 may include a second lower electrode pattern 151 on a corresponding (e.g., coupled) one of the common column lines 120, a second variable resistance pattern 153, and a second upper electrode pattern 155.

The first lower electrode pattern 141 may be located on the first row line 110. The first lower electrode pattern 141 may be a portion of the first row line 110, or may be electrically connected to the first row line 110. The first upper electrode pattern 145 may be located on the first lower electrode pattern 141. The first upper electrode pattern 145 may be a portion of the common column line 120, or may be electrically connected to the common column line 120. The first variable resistance pattern 143 may be located between the first lower electrode pattern 141 and the first upper electrode pattern 145.

The second lower electrode pattern 151 may be located on the common column line 120. The second lower electrode pattern 151 may be a portion of the common column line 120, or may be electrically connected to the common column line 120. The second upper electrode pattern 155 may be located on the second lower electrode pattern 151. The second upper electrode pattern 155 may be a portion of the second low line 130, or may be electrically connected to the second low line 130. The second variable resistance pattern 153 may be located between the second lower electrode pattern 151 and the second upper electrode pattern 155.

At least one of the first lower electrode pattern 141, the first upper electrode pattern 145, the second lower electrode pattern 151, or the second upper electrode pattern 155 may include polysilicon, tungsten (W), tungsten nitride (WNx), tungsten silicide (WSix), titanium (Ti), titanium nitride (TiNx), titanium silicon nitride (TiSiN), titanium aluminum nitride (TiAIN), tantalum (Ta), tantalum nitride (TaN), tantalum silicon nitride (TaSiN), tantalum aluminum nitride (TaAIN), carbon (C), silicon carbide (SiC), silicon carbon nitride (SiCN), copper (Cu), zinc (Zn), nickel (Ni), cobalt (Co), lead (Pb), platinum (Pt), molybdenum (Mo), ruthenium (Ru), or the like, and may include a combination thereof.

At least one of the first variable resistance pattern 143 or the second variable resistance pattern 153 may include a resistive material, and may have a characteristic of reversibly changing between different resistance states according to an applied voltage or current.

At least one of the first variable resistance pattern 143 or the second variable resistance pattern 153 may be used as a data storage and selection element. For example, at least one of the first variable resistance pattern 143 or the second variable resistance pattern 153 may maintain an amorphous state during a program operation, and may not change to a crystalline state after the program operation. In other words, a phase of at least one of the first variable resistance pattern 143 or the second variable resistance pattern 153 may not change after the program operation. For example, at least one of the first variable resistance pattern 143 or the second variable resistance pattern 153 may include a variable resistance material of which a resistance changes without a phase change, and may include a chalcogenide element. At least one of the first variable resistance pattern 143 or the second variable resistance pattern 153 may include germanium (Ge), antimony (Sb), arsenic (As), silicon (Si), indium (In), tin (Sn), gallium (Ga), or the like, or may include a combination thereof.

At least one of the first variable resistance pattern 143 or the second variable resistance pattern 153 may include a phase change material, and may include a chalcogenide. At least one of the first variable resistance pattern 143 or the second variable resistance pattern 153 may include a chalcogenide glass, a chalcogenide alloy, or the like. A phase of at least one of the first variable resistance pattern 143 or the second variable resistance pattern 153 may be changed according to a program operation. For example, at least one of the first variable resistance pattern 143 or the second variable resistance pattern 153 may have a low resistance crystalline state by a set operation. In addition, at least one of the first variable resistance pattern 143 or the second variable resistance pattern 153 may have a high resistance amorphous state by a reset operation. Therefore, at least one of the first variable resistance pattern 143 or the second variable resistance pattern 153 may store data in at least one of a first memory cell MC1 or a second memory cell MC2 by using a resistance difference according to the phase.

At least one of the first variable resistance pattern 143 or the second variable resistance pattern 153 may include metal oxide (transition metal oxide), or may include metal oxide such as a perovskite material. Therefore, an electrical path may be generated or extinguished in the variable resistance pattern 143 and the second variable resistance pattern 153, and thus data may be stored in the first and second memory cells MC1 and MC2.

At least one of the first variable resistance pattern 143 or the second variable resistance pattern 153 may have an MTJ structure, and may include a magnetization fixed layer, a magnetization free layer, and a tunnel barrier layer interposed therebetween. For example, the magnetization fixed layer and the magnetization free layer may include a magnetic material, and the tunnel barrier layer may include oxide such as magnesium (Mg), aluminum (Al), zinc (Zn), or titanium (Ti). Here, a magnetization direction of the magnetization free layer may be changed by spin torque of electrons in the applied current. Therefore, data may be stored in the first memory cell MC1 according to a change of the magnetization direction of the magnetization free layer with respect to a magnetization direction of the magnetization fixed layer.

In addition, at least one of the first variable resistance pattern 143 or the second variable resistance pattern 153 may have a metal insulator metal (MIM) structure including metal oxide. In this case, data may be stored in the first memory cell MC1 or the second memory cell MC2 by using a resistance change of the metal oxide that occurs by applying a short electric pulse.

For reference, although not shown in this drawing, the semiconductor device may further include a first intermediate electrode pattern, a second intermediate electrode pattern, a first switching pattern, and a second switching pattern. For example, the semiconductor device may include a structure in which the first lower electrode pattern 141, the first switching pattern, the first intermediate electrode pattern, the first variable resistance pattern 143, and the first upper electrode pattern 145 are sequentially stacked. In addition, the semiconductor device may include a structure in which the second lower electrode pattern 151, the second switching pattern, the second intermediate electrode pattern, the second variable resistance pattern 153, and the second upper electrode pattern 155 are sequentially stacked.

In this case, the first lower electrode pattern 141, the first switching pattern, and the first intermediate electrode pattern may configure a first selection element, and the second lower electrode pattern 151, the second switching pattern, and the second intermediate electrode pattern may configure a second selection element. The first and second selection elements may be a diode, a PNP diodes, a transistor, a vertical transistor, a bipolar junction transistor (BIT), a metal insulator transition (MIT) element, a mixed ionic-electronic conduction (MIEC) element, an ovonic threshold switching (OTS) element, and the like. For example, the first and second switching patterns may include a chalcogenide material.

In addition, the first intermediate electrode pattern, the first variable resistance pattern 143, and the first upper electrode pattern 145 may configure a first memory element, and the second intermediate electrode pattern, the second variable resistance pattern 153, and the second upper electrode pattern may configure a second memory element. The first and second memory elements and the first and second selection elements may share the first and second intermediate electrode patterns, respectively.

The first liner patterns LN1 each may cover at least a sidewall of each of the first memory cells MC1 neighboring in the second direction II. Specifically, each of the first liner patterns LN1 may extend over sidewalls of a pair of first memory cells MC1 neighboring in the second direction II. Each of the first liner patterns LN1 may also extend in the first direction I to cover a plurality of sidewalls of a plurality of first memory cells MC1 neighboring in the second direction II. The first liner patterns LN1 each may cover the sidewall of each of the first memory cells MC1, and may extend over a sidewall of each of the first row lines 110. For example, each of the first liner patterns LN1 may extend over the first row line 110, the first lower electrode pattern 141, the first variable resistance pattern 143, and the first upper electrode pattern 145.

The second liner patterns LN2 each may cover at least a sidewall of each of the first memory cells MC1 neighboring in the first direction I. Specifically, each of the second liner patterns LN2 may extend over sidewalls of a pair of first memory cells MC1 neighboring in the first direction I. The second liner patterns LN2 each may cover the sidewall of each of the first memory cells MC1, and may extend over a sidewall of each of the common column lines 120. For example, the second liner patterns LN2 each may extend over the first lower electrode pattern 141, the first variable resistance pattern 143, the first upper electrode pattern 145, and the common column line 120.

The third liner patterns LN3 each may cover at least a sidewall of each of the second memory cells MC2 neighboring in the first direction I. Specifically, each of the third liner patterns LN3 may extend over sidewalls of a pair of second memory cells MC2 neighboring in the first direction I. For example, each of the third liner patterns LN3 may extend over the second lower electrode pattern 151, the second variable resistance pattern 153, and the second upper electrode pattern 155. In some embodiments, each of the third liner patterns LN3 may extend over the second upper electrode pattern 155, the second variable resistance pattern 153, the second lower electrode pattern 151, the common column line 120, the first upper electrode pattern 145, and the first variable resistance pattern 143. In some embodiments, each of the third liner patterns LN3 may extend over the second upper electrode pattern 155, the second variable resistance pattern 153, the second lower electrode pattern 151, the common column line 120, the first upper electrode pattern 145, the first variable resistance pattern 143 and the first lower electrode pattern 141. In other words, the third liner patterns LN3 may extend along a surface of the second liner patterns LN2. Specifically, each of the third liner patterns LN3 may extend over a portion of a surface of a corresponding one (e.g., abutting) of the second liner patterns LN2. For example, a lower surface of the third liner pattern LN3 may be located below a lower surface of the first upper electrode pattern 145. In some embodiments, each of the second liner patterns LN2 and each of the third liner patterns LN3 cover at least a sidewall of the first upper electrode pattern 145. For example, each of the second liner patterns LN2 and each of the third liner patterns LN3 cover a pair of sidewalls of the first upper electrode patterns 145 of the first memory cells MC1 neighboring in the first direction I.

The fourth liner patterns LN4 each may cover at least a sidewall of each of the second memory cells MC2 neighboring in the second direction II. Specifically, each of the fourth liner patterns LN4 may extend over sidewalls of a pair of second memory cells MC2 neighboring in the second direction II. Each of the fourth liner patterns LN4 may also extend in the first direction I to cover a plurality of sidewalls of a plurality of second memory cells MC2 neighboring in the second direction II. For example, each of the fourth liner patterns LN4 may extend over the second lower electrode pattern 151, the second variable resistance pattern 153, the second upper electrode pattern 155, and the second row line 130. Here, at least one of the first liner patterns LN1, the second liner patterns LN2, the third liner patterns LN3, or the fourth liner patterns LN4 may include oxide or nitride. For example, the first, second, third, and fourth liner patterns LN1, LN2, LN3, and LN4 may include nitride.

When forming memory cells with a multi-deck structure in a conventional semiconductor device, memory cells of a lower deck may be damaged in a process of forming memory cells of an upper deck. In this case, a sidewall of the memory cell may be covered by a liner pattern to reduce damage to the memory cells of the lower deck. However, when a single liner pattern covering the sidewall of the memory cells exists, oxygen existing in a gap fill pattern of the lower deck may diffuse into the liner pattern through a process such as applying heat to the conventional semiconductor device in the process of forming the memory cells of the upper deck, and the liner pattern may be relatively easily deteriorated. Therefore, reliability of the memory cells of the lower deck may be deteriorated.

According to an embodiment of the present disclosure, the third liner pattern LN3 may extend over a surface of the second liner pattern LN2, and may cover the sidewalls of the first memory cells MC1. In other words, the sidewalls of the first memory cell MC1 corresponding to the lower deck may be covered by dual liner patterns (e.g., the second and third liner patterns LN2 and LN3). In this case, in a process of forming the second memory cells MC2 corresponding to the upper deck, deterioration of reliability of the first memory cell MC1 may be substantially prevented or reduced compared to a case where the sidewall of the first memory cell MC1 is covered by a single second liner pattern.

In addition, when a memory cell repeatedly performs program and erase operations, a material included in a variable resistance pattern of the memory cell may diffuse to an outside, and reliability of the memory cell may be deteriorated. For example, when a memory cell including a variable resistance pattern and an upper electrode pattern is repeatedly operated, a volume of an area adjacent to an upper surface of the variable resistance pattern may repeatedly expand or contract, and a chalcogenide element included in the variable resistance pattern may be separated from the variable resistance pattern and moved toward the upper electrode pattern. In this case, adhesive strength between the upper electrode pattern and a liner pattern covering the upper electrode pattern may be weakened, and a peeling phenomenon in which the upper electrode pattern and the liner pattern are separated may occur.

According to an embodiment of the present disclosure, the third liner pattern LN3 may cover a sidewall of the first upper electrode pattern 145 over a surface of the second liner pattern LN2. In other words, the sidewall of the first upper electrode pattern 145 may be covered by dual linear patterns (e.g., the second and third liner patterns LN2 and LN3). In this case, because the second and third liner patterns LN2 and LN3 may simultaneously apply pressure to the first upper electrode pattern 145, occurrence of a peeling phenomenon in which the first upper electrode pattern 145 and the second liner pattern LN2 are separated may be substantially prevented or reduced compared to a case where the sidewall of the first upper electrode pattern 145 is covered by a single second liner pattern LN2.

The first gap fill patterns GF1 may be located between the first memory cells MC1 neighboring in the second direction II. The first liner patterns LN1 may be located between the first gap fill patterns GF1 and the first memory cells MC1.

The second gap fill patterns GF2 may be located between the first memory cells MC1 neighboring in the first direction I. For example, each of the second gap fill patterns GF2 may be located between a corresponding (e.g., adjacent to) pair of first memory cells MC1 neighboring in the first direction I. The second liner patterns LN2 may be located between the second gap fill patterns GF2 and the first memory cells MC1. For example, each of the second liner patterns LN2 may be located between a corresponding (e.g., abutting) one of the second gap fill patterns GF2 and a corresponding (e.g., abutting) pair of first memory cells MC1 neighboring in the first direction I.

The third gap fill patterns GF3 may be located between the second memory cells MC2 neighboring in the first direction I. For example, each of the third gap fill patterns GF3 may be located between a corresponding (e.g., adjacent to) pair of second memory cells MC2 neighboring in the first direction I. In addition, the third gap fill patterns GF3 may extend between the first memory cells MC1 neighboring in the first direction I. The third liner patterns LN3 may be located between the third gap fill patterns GF3 and the second memory cells MC2. For example, each of the third liner patterns LN3 may be located between a corresponding (e.g., abutting) one of the third gap fill patterns GF3 and a corresponding (e.g., abutting) pair of the second memory cells MC2 neighboring in the first direction I. In addition, the third liner patterns LN3 may extend between the third gap fill patterns GF3 and the second gap fill patterns GF2.

The fourth gap fill patterns GF4 may be located between the second memory cells MC2 neighboring in the second direction II. The fourth liner patterns LN4 may be located between the fourth gap fill patterns GF4 and the second memory cells MC2.

At least one of the first gap fill patterns GF1, the second gap fill patterns GF2, the third gap fill patterns GF3, or the fourth gap fill patterns GF4 may include an insulating material such as oxide or nitride. For example, the first gap fill patterns GF1, the second gap fill patterns GF2, the third gap fill patterns GF3, and the fourth gap fill patterns GF4 may include oxide.

The first gap fill patterns GF1 may have a first height H1. The second gap fill patterns GF2 may have a second height H2. The third gap fill patterns GF3 may have a third height H3. The fourth gap fill patterns GF4 may have a fourth height H4. The first gap fill patterns GF1 may have substantially the same height as the fourth gap fill patterns GF4. For example, the first height H1 and the fourth height H4 may be substantially the same. The second gap fill patterns GF2 and the third gap fill patterns GF3 may have different heights. For example, the second height H2 may be less than the third height H3. This is because the third gap fill patterns GF3 are formed at a location where the second gap fill patterns GF2 are partially etched and removed in a process of manufacturing the semiconductor device.

According to the structure described above, the sidewall of the first memory cells MC1 may be covered by the second and third liner patterns LN2 and LN3. For example, the sidewall of the first upper electrode pattern 145 may be covered by the second and third liner patterns LN2 and LN3. In this case, the first upper electrode pattern 145 and the second liner pattern LN2 may be substantially prevented from being separated, and reliability of the first memory cell MC1 corresponding to the lower deck may be ensured.

In addition, because the first memory cells MC1 and the second memory cells MC2 may be stacked, an integration degree of the semiconductor device may be improved. Here, in addition, an integration degree of the semiconductor device may be further improved by additionally forming third memory cells and the like.

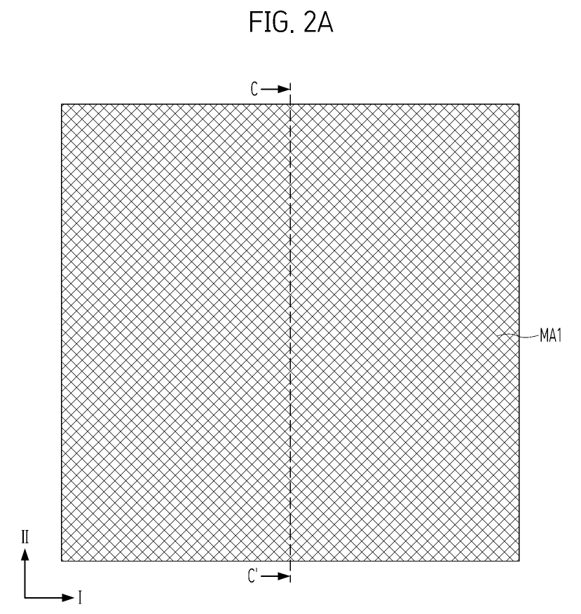

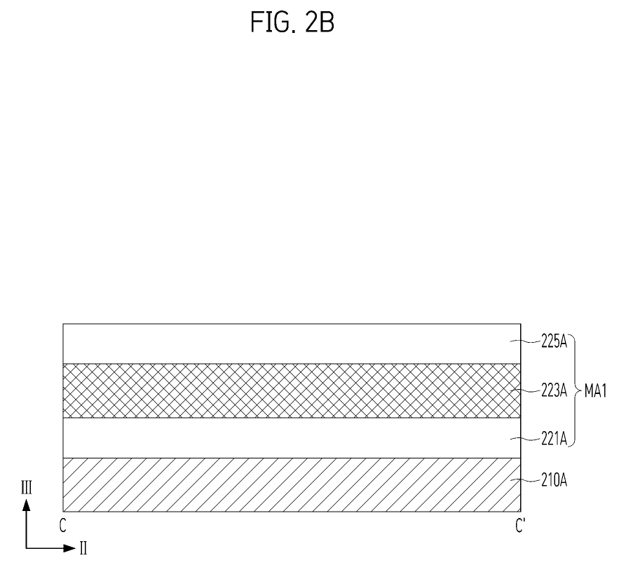

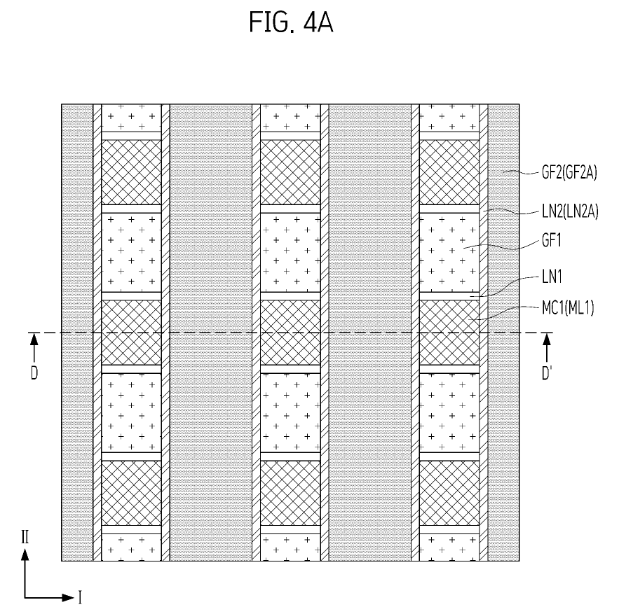

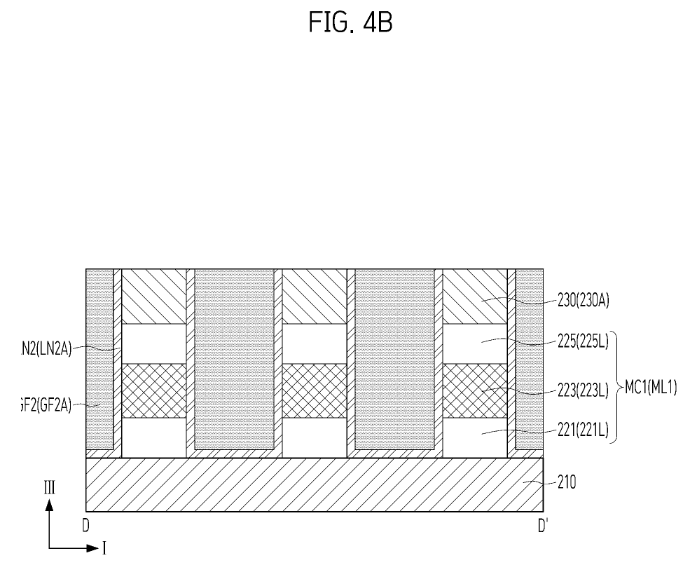

FIGS. 2A, 2B, 3A, 3B, 4A, 4B, 5A, 5B, 6A, 6B, 7A, 7B, and 8A to 8C are drawings illustrating a method of manufacturing a semiconductor device according to an embodiment of the present disclosure. FIGS. 2A, 3A, 4A, 5A, 6A, 7A, and 8A are plan views, FIGS. 2B, 3B, and 8B are cross-sectional views taken along line C-C' of FIGS. 2A, 3A, and 8A, respectively, and FIGS. 4B, 5B, 6B, 7B, and 8C are cross-sectional views taken along line D-D' of FIGS. 4A, 5A, 6A, 7A, and 8A, respectively. Hereinafter, a content that overlaps the content described above may be omitted for the interest of brevity.

Referring to FIGS. 2A and 2B, a first memory layer MA1 may be formed on a first conductive layer 210A. For example, a first lower electrode layer 221A, a first variable resistance layer 223A, and a first upper electrode layer 225A may be sequentially stacked on the first conductive layer 210A to form the first memory layer MA1. Here, the first conductive layer 210A may include a conductive material such as tungsten.

For reference, the first memory layer MA1 may further include a first switching layer (not shown) and a first intermediate electrode layer (not shown). Here, the first switching layer may be formed between the first lower electrode layer 221A and the first intermediate electrode layer, and the first intermediate electrode layer may be formed between the first switching layer and the first variable resistance layer 223A.

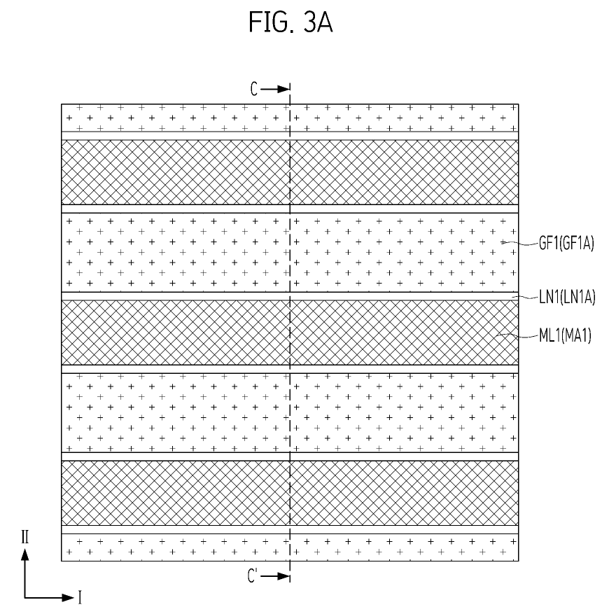

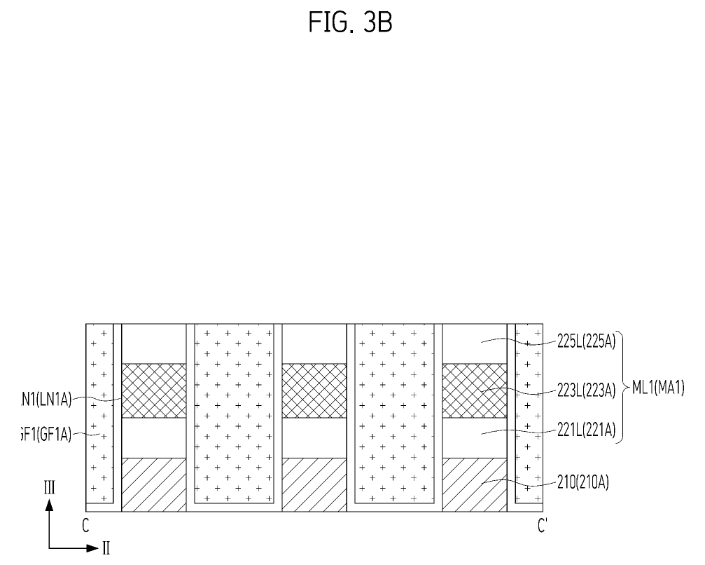

Referring to FIGS. 3A and 3B, first memory lines ML1 extending in a first direction I may be formed. For example, the first upper electrode layer 225A, the first variable resistance layer 223A, and the first lower electrode layer 221A may be sequentially etched to form the first memory lines ML1 including first upper electrode lines 225L, first variable resistance lines 223L, and first lower electrode lines 221L. For reference, the first memory line ML1 may further include a first intermediate electrode line (not shown) and a first switching line (not shown).

The first conductive layer 210A may be etched to form first row lines 210 extending in the first direction I. The first row lines 210 may be used as a word line or a bit line.

Subsequently, a first liner layer LN1A may be formed on the first memory lines ML1. For example, the first liner layer LN1A may be formed along a profile of the first memory lines ML1. Here, the first liner layer LN1A may include an insulating material such as nitride.

Subsequently, a first gap fill layer GF1A may be formed on the first liner layer LN1A. For example, the first gap fill layer GF1A may be formed to fill a space between the first memory lines ML1. Here, the first gap fill layer GF1A may include a material having an etching selectivity with respect to the first liner layer LN1A. For example, the first gap fill layer GF1A may include an insulating material such as oxide.

Subsequently, the first gap fill layer GF1A may be planarized so that an upper surface of each of the first memory lines ML1 is exposed. In this process, the first gap fill layer GF1A may be separated into first gap fill patterns GF1. In addition, the first liner layer LN1A may be separated into first liner patterns LN1. Therefore, the first liner patterns LN1 may be formed on the first memory lines ML1, and the first gap fill patterns GF1 may be formed on the first liner patterns LN1.

Referring to FIGS. 4A and 4B, a second conductive layer 230A may be formed on the first memory lines ML1. Subsequently, common column lines 230 extending in a second direction II that crosses the first direction I may be formed. For example, the second conductive layer 230A may be etched to form the common column lines 230.

Subsequently, the first memory cells MC1 may be formed. For example, the first memory lines ML1 may be etched to form the first memory cells MC1. Here, each of the first memory cells MC1 may include a first lower electrode pattern 221, a first variable resistance pattern 223, and a first upper electrode pattern 225. For reference, the first memory cell MC1 may further include a first switching pattern (not shown) and a first intermediate electrode pattern (not shown).

Subsequently, a second liner layer LN2A may be formed on the first memory cells MC1. For example, the second liner layer LN2A may be formed along a profile of the first memory cells MC1 between the first memory cells MC1. Here, the second liner layer LN2A may include substantially the same material as the first liner layer LN1A. For example, the second liner layer LN2A may include an insulating material such as nitride.

Subsequently, a second gap fill layer GF2A may be formed on the second liner layer LN2A. For example, the second gap fill layer GF2A may be formed to fill a space between the first memory cells MC1. Here, the second gap fill layer GF2A may include a material having an etching selectivity with respect to the second liner layer LN2A. For example, the second gap fill layer GF2A may include an insulating material such as oxide.

Subsequently, the second gap fill layer GF2A may be planarized so that an upper surface of each of the common column lines 230 is exposed. In this process, the second gap fill layer GF2A may be separated into second gap fill patterns GF2. In addition, the second liner layer LN2A may be separated into second liner patterns LN2. Therefore, the second liner patterns LN2 may be formed on the first memory cells MC1, and the second gap fill patterns GF2 may be formed on the second liner patterns LN2.

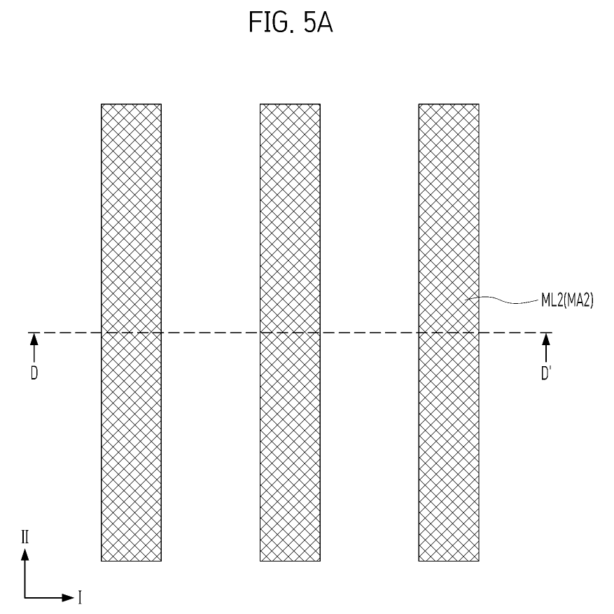

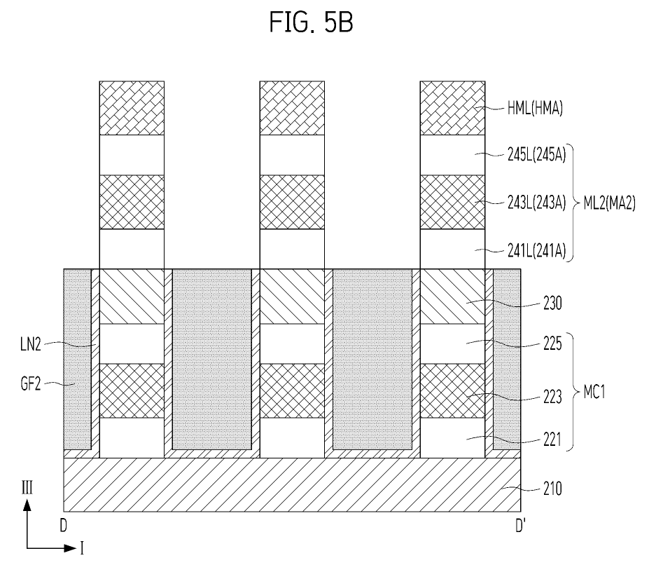

Referring to FIGS. 5A and 5B, second memory lines ML2 extending in the second direction II may be formed on the common column lines 230. First, the second memory layer MA2 may be formed on the common column lines 230. Subsequently, a hard mask layer HMA may be formed on the second memory layer MA2. Here, the second memory layer MA2 may include a second lower electrode layer 241A, a second variable resistance layer 243A, and a second upper electrode layer 245A. For reference, the second memory layer MA2 may further include a second intermediate electrode layer (not shown) and a second switching layer (not shown).

Subsequently, the second memory layer MA2 may be etched to form second memory lines ML2. For example, the second memory layer MA2 may be etched using the hard mask layer HMA as an etching barrier to form the second memory lines ML2. In this process, the hard mask layer HMA may be separated into hard mask lines HML. Here, the second memory lines ML2 may include second lower electrode lines 241L, second variable resistance lines 243L, and second upper electrode lines 245L. For reference, the second memory lines ML2 may further include second intermediate electrode lines (not shown) and second switching lines (not shown).

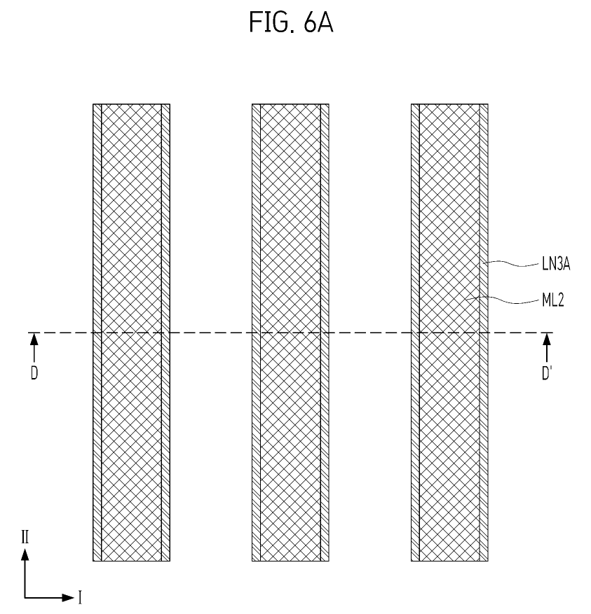

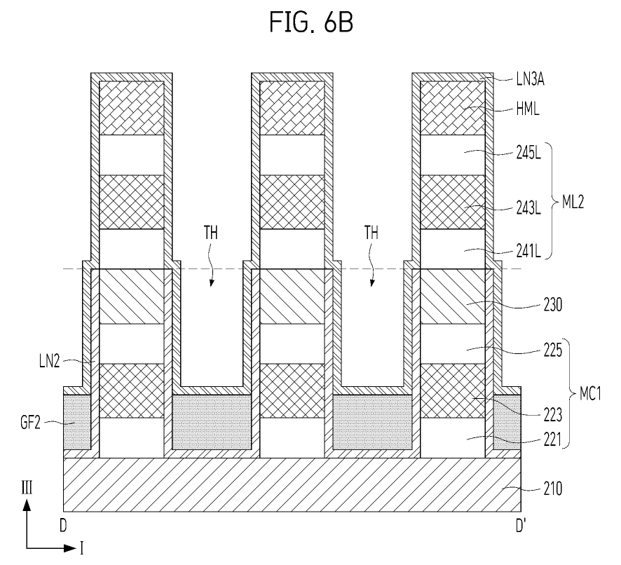

Referring to FIGS. 6A and 6B, the second gap fill patterns GF2 may be etched to form trenches TH exposing the second liner patterns LN2. For example, the second gap fill patterns GF2 may be partially etched to form the trenches TH so that an upper surface of each of the etched second gap fill patterns GF2 is located below a lower surface of each of the first upper electrode pattern 225. Because the second gap fill patterns GF2 may include a material having an etching selectivity with respect to the second liner patterns LN2, the second gap fill patterns GF2 may be partially etched by controlling an etching time or the like.

Subsequently, a third liner layer LN3A may be formed in the trenches TH. For example, the third liner layer LN3A that extends into trenches TH and over at least a sidewall of each the second memory lines ML2 neighboring in the first direction I may be formed. In the embodiment shown in FIGS. 6A and 6B, the third liner layer LN3A may be formed to extend over sidewalls of the second memory lines ML2 neighboring in the first direction I and sidewalls of and upper surfaces of the hard mask lines HML neighboring in the first direction I. The third liner layer LN3A may extend over the second memory line ML2, the common column line 230, the first upper electrode pattern 225, and the first variable resistance pattern 223. Here, the third liner layer LN3A may include an insulating material such as nitride.

For reference, in the embodiment of FIG. 6B, the second gap fill patterns GF2 are partially etched, but embodiments of the present disclosure are not limited thereto. In some embodiments, the second gap fill patterns GF2 may be substantially entirely removed. In this case, the trenches TH may be formed so that the second liner patterns LN2 contacting the first row line 210 are exposed, and the third liner layer LN3A may be formed in the trenches TH along a surface of the second liner patterns LN2. In this case, the third liner layer LN3A may be formed to contact the second liner patterns LN2 contacting the first row line 210.

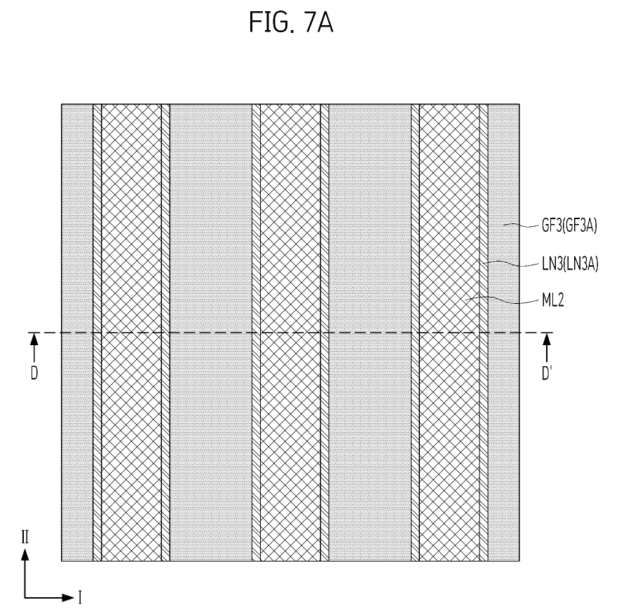

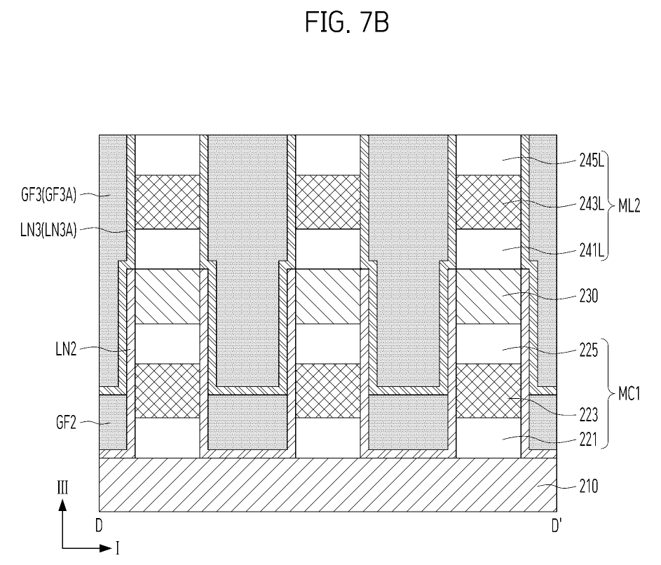

Referring to FIGS. 7A and 7B, a third gap fill layer GF3A may be formed in the trenches TH. For example, the third gap fill layer GF3A may be formed to fill the trenches TH formed between the first memory cells MC1, and the third gap fill layer GF3A may be formed to fill spaces between the second memory lines ML2. Here, the third gap fill layer GF3A may include an insulating material such as oxide.

Subsequently, the third gap fill layer GF3A may be planarized so that an upper surface of each of the second memory lines ML2 is exposed. In this process, the hard mask lines HML may be removed. In addition, the third gap fill layer GF3A may be separated into third gap fill patterns GF3. In addition, the third liner layer LN3A may be separated into third liner patterns LN3. In some embodiments, when the second gap fill patterns GF2 are substantially entirely removed, the third liner layer LN3A may extend along the second liner patterns LN2 contacting the first row line 210, and thus the third liner patterns LN3 may be formed to contact the second liner patterns LN2 contacting the first row line 210. Specifically, each of the third liner patterns LN3 may contact a corresponding one of the second liner patterns LN2 that contact the first row line 210.

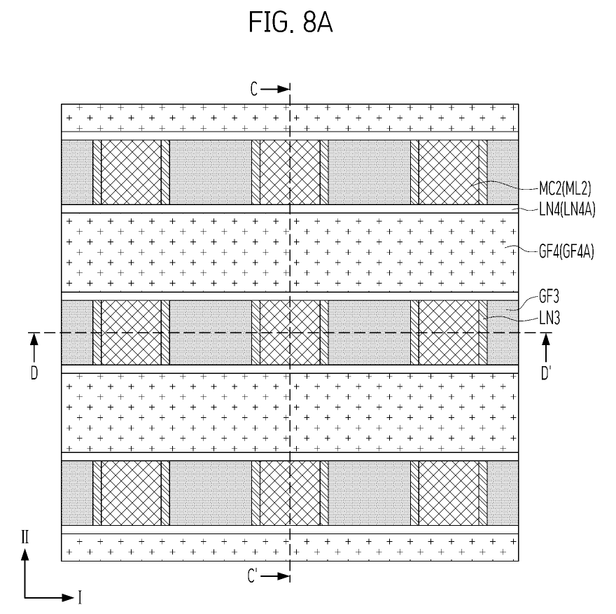

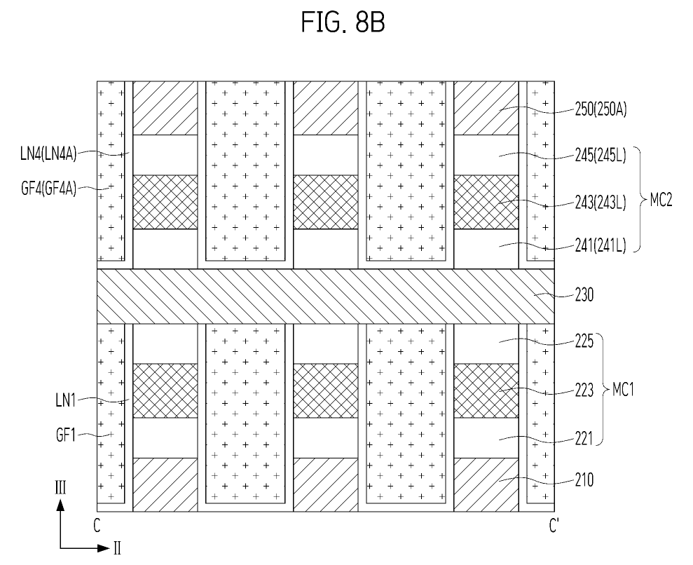

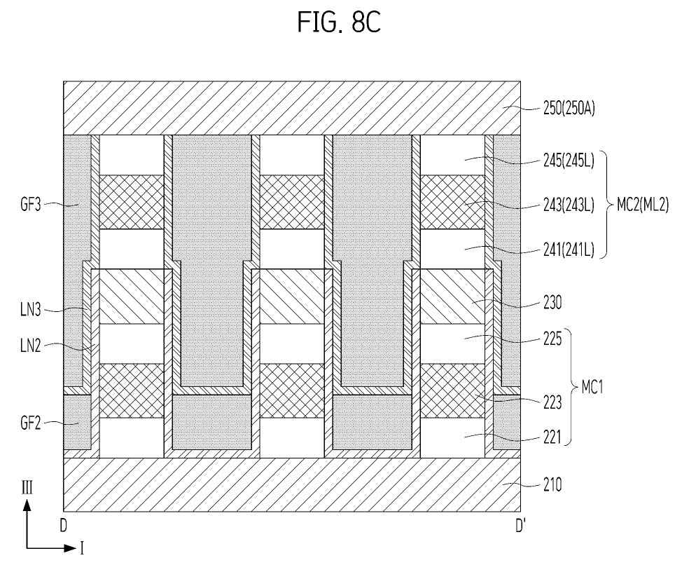

Referring to FIGS. 8A to 8C, second row lines 250 extending in the first direction I may be formed. First, a third conductive layer 250A may be formed on the second memory lines ML2. Subsequently, the third conductive layer 250A may be etched to form the second row lines 250.

Subsequently, the second memory lines ML2 may be etched to form second memory cells MC2. Here, each of the second memory cells MC2 may include a second lower electrode pattern 241, a second variable resistance pattern 243, and a second upper electrode pattern 245. For reference, the second memory cell MC2 may further include a second intermediate electrode pattern (not shown) and a second switching pattern (not shown).

Subsequently, a fourth liner layer LN4A may be formed on the second memory cells MC2. Subsequently, a fourth gap fill layer GF4A may be formed on the fourth liner layer LN4A. Here, the fourth liner layer LN4A may include an insulating material such as nitride, and the fourth gap fill layer GF4A may include an insulating material such as oxide.

Subsequently, the fourth gap fill layer GF4A may be planarized so that the second row lines 250 are exposed. In this process, the fourth gap fill layer GF4A may be separated into fourth gap fill patterns GF4. In addition, the fourth liner layer LN4A may be separated into fourth liner patterns LN4.

When forming memory cells with a multi-deck structure in a conventional semiconductor device, memory cells of a lower deck may be damaged in a process of forming memory cells of an upper deck. In this case, a sidewall of the memory cell may be covered by a liner pattern to reduce damage to the memory cells of the lower deck. However, when a single liner pattern covering the sidewall of the memory cells exists, oxygen existing in a gap fill pattern of the lower deck may diffuse into the liner pattern through a process such as applying heat to the conventional semiconductor device in the process of forming the memory cells of the upper deck, and the liner pattern may be relatively easily deteriorated. Therefore, reliability of the memory cells of the lower deck may be deteriorated.

According to an embodiment of the present disclosure, the sidewall of the first memory cell MC1 may be covered by dual liner patterns (e.g., the second liner pattern LN2 and the third liner pattern LN3). In this case, in a process of forming the second memory cells MC2 corresponding to the upper deck, even though oxygen existing in the second gap fill pattern GF2 diffuses into the third liner pattern LN3 and the third liner pattern LN3 is deteriorated, the second liner pattern LN2 may protect the first memory cell MC1. Therefore, deterioration of reliability of the first memory cell MC1 may be substantially prevented or reduced compared to a case where the sidewall of the first memory cell MC1 is covered by a single second liner pattern LN2.

In addition, when a memory cell repeatedly performs program and erase operations, a material included in a variable resistance pattern of the memory cell may diffuse to an outside, and reliability of the memory cell may be deteriorated. For example, when a memory cell including a variable resistance pattern and an upper electrode pattern is repeatedly operated, a volume of an area adjacent to an upper surface of the variable resistance pattern may repeatedly expand or contract, and a chalcogenide element included in the variable resistance pattern may be separated from the variable resistance pattern and moved toward the upper electrode pattern. In this case, adhesive strength between the upper electrode pattern and a liner pattern covering the upper electrode pattern may be weakened, and a peeling phenomenon in which the upper electrode pattern and the liner pattern are separated may occur.

According to an embodiment of the present disclosure, a sidewall of the first upper electrode pattern 225 may be covered by dual linear patterns (e.g., the second liner pattern LN2 and the third liner pattern LN3). In this case, because the second and third liner patterns LN2 and LN3 may simultaneously apply pressure to the first upper electrode pattern 225, occurrence of a peeling phenomenon in which the first upper electrode pattern 225 and the second liner pattern LN2 are separated may be substantially prevented or reduced compared to a case where the sidewall of the first upper electrode pattern 225 is covered by a single second liner pattern LN2.

According to the manufacturing method described above, the second gap fill patterns GF2 may be etched to form the trenches TH exposing the second liner patterns LN2. Subsequently, the third liner layer LN3A may be formed along the second liner patterns LN2 in the trenches TH. In this case, by covering the sidewall of the first memory cell MC1 with the second liner pattern LN2 and the third liner layer LN3A, the first memory cell MC1 may be substantially prevented from being deteriorated. In addition, even though the first memory cells MC1 are repeatedly operated, the first upper electrode pattern 225 and the second liner pattern LN2 may be substantially prevented from being separated from each other.

Although some embodiments of the present disclosure have been described above with reference to the accompanying drawings, various embodiments of the present disclosure are not limited to the above-described embodiments. Substitution, modification, and change of the embodiments may be possible by those skilled in the art to which the present disclosure belongs, and these embodiments also belong to various embodiments of the present disclosure.

What is claimed is:

1. A semiconductor device comprising:
first row lines extending in a first direction;
common column lines located on the first row lines and extending in a second direction that crosses the first direction;
second row lines located on the common column lines and extending in the first direction;
first memory cells located between the first row lines and the
common column lines, respectively;second memory cells located between the common column lines and the second row lines, respectively;second liner patterns each covering at least a sidewall of each of the first memory cells neighboring in the first direction; andthird liner patterns each covering at least a sidewall of each of the second memory cells neighboring in the first direction and extending over a corresponding one of the second liner patterns.

2. The semiconductor device of claim 1, wherein each of the
second liner patterns extends over sidewalls of a pair of the first memory cells neighboring in the first direction, and wherein each of the third liner patterns extends over sidewalls of a pair of second memory cells neighboring in the first direction, and extends over a portion of a surface of the corresponding one of the
second linear patterns.

3. The semiconductor device of claim 1, further comprising:
first gap fill patterns located between the first memory cells
neighboring in the second direction;second gap fill patterns located between the first memory cells neighboring in the first direction;third gap fill patterns located between the first memory cells neighboring in the first direction and the second memory cells
neighboring in the first direction; andfourth gap fill patterns located between the second memory cells neighboring in the second direction.

4. The semiconductor device of claim 3, wherein at least one
of the second liner patterns or the third liner patterns includes nitride,
and wherein at least one of the first gap fill patterns, the second gap fill patterns, the third gap fill patterns, or the fourth gap fill patterns includes oxide.

5. The semiconductor device of claim 3, wherein the third liner patterns extend between the second gap fill patterns and the third gap fill patterns.

6. The semiconductor device of claim 3, wherein the first gap fill patterns have substantially the same height as the fourth gap fill patterns, and
wherein the second gap fill patterns have a height less than a
height of the third gap fill patterns.

7. The semiconductor device of claim 1, further comprising:
first liner patterns each covering at least a sidewall of each of the first memory cells neighboring in the second direction; and
fourth liner patterns each covering at least a sidewall of each of the second memory cells neighboring in the second direction.

8. The semiconductor device of claim 7, wherein each of the first liner patterns extends over the first upper electrode pattern, the
first variable resistance pattern, the first lower electrode pattern, and
the first row line, andwherein each of the fourth liner patterns extends over the second row line, the second upper electrode pattern, the second variable resistance pattern, and the second lower electrode pattern.

9. The semiconductor device of claim 1, wherein each of the first memory cells includes a first lower electrode pattern located on the first row line, a first variable resistance pattern located on the first lower electrode pattern, and a first upper electrode pattern located on the
first variable resistance pattern, andwherein each of the second memory cells includes a second lower electrode pattern located on the common column line, a second variable resistance pattern located on the second lower electrode pattern, and a second upper electrode pattern located on the second variable resistance pattern.

10. The semiconductor device of claim 9, wherein each of the second liner patterns extends over the common column line, the first
upper electrode pattern, the first variable resistance pattern, and the first lower electrode pattern, andwherein each of the third liner patterns extends over the second upper electrode pattern, the second variable resistance pattern, the second lower electrode pattern, the common column line, the first
upper electrode pattern, and the first variable resistance pattern.

11. The semiconductor device of claim 9, wherein each of the third liner patterns extends over the second upper electrode pattern, the second variable resistance pattern, the second lower electrode
pattern, the common column line, the first upper electrode pattern, the first variable resistance pattern, and the first lower electrode pattern.

12. The semiconductor device of claim 11, wherein each of the third liner patterns contacts a corresponding one of the second liner
patterns contacting the first row line.

13. The semiconductor device of claim 9, wherein each of the second liner patterns and each of the third liner patterns cover at least
a sidewall of the first upper electrode pattern.

14. The semiconductor device of claim 9, wherein a lower surface of each of the third liner patterns is located below a lower surface of the first upper electrode pattern.

15. A semiconductor device comprising:
first row lines extending in a first direction;
common column lines located on the first row lines and extending in a second direction that crosses the first direction;
second row lines located on the common column lines and extending in the first direction;
first memory cells located between the first row lines and the common column lines, respectively;
second memory cells located between the common column lines
and the second row lines, respectively;second gap fill patterns located between the first memory cells neighboring in the first direction; andthird gap fill patterns located between the second memory cells neighboring in the first direction and extending between the first
memory cells.

16. The semiconductor device of claim 15, further comprising:
second liner patterns each covering at least a sidewall of each of
the first memory cells neighboring in the first direction; andthird liner patterns each covering at least a sidewall of each of the second memory cells neighboring in the first direction and extending over a corresponding one of the second liner patterns.

17. The semiconductor device of claim 16, wherein the third liner patterns extend between the second gap fill patterns and the third gap fill patterns.

18. The semiconductor device of claim 16, wherein each of the
first memory cells includes a first lower electrode pattern located on the first row line, a first variable resistance pattern located on the first lower electrode pattern, and a first upper electrode pattern located on the first variable resistance pattern, andwherein each of the second memory cells includes a second lower
electrode pattern located on the common column line, a second variable resistance pattern located on the second lower electrode pattern, and
a second upper electrode pattern located on the second variable resistance pattern.

19. The semiconductor device of claim 18, further comprising:
first liner patterns each covering at least a sidewall of each of the first memory cells neighboring in the second direction; and
fourth liner patterns each covering at least a sidewall of each of
the second memory cells neighboring to the second direction,wherein each of the first liner patterns extends over the first upper electrode pattern, the first variable resistance pattern, the first lower electrode pattern, and the first row line, andwherein each of the fourth liner patterns extends over the second
row line, the second upper electrode pattern, the second variable resistance pattern, and the second lower electrode pattern.

20. The semiconductor device of claim 18, wherein each of the second liner patterns extends over the common column line, the first
upper electrode pattern, the first variable resistance pattern, and the first lower electrode pattern, andwherein each of the third liner patterns extends over the second upper electrode pattern, the second variable resistance pattern, the second lower electrode pattern, the common column line, the first
upper electrode pattern, and the first variable resistance pattern.

21. The semiconductor device of claim 18, wherein each of the second liner patterns and each of the third liner patterns cover at least a sidewall of the first upper electrode pattern.

22. The semiconductor device of claim 18, wherein a lower surface of each of the third liner patterns is located below a lower surface of the first upper electrode pattern.

23. The semiconductor device of claim 15, further comprising:
first gap fill patterns located between the first memory cells neighboring in the second direction; and
fourth gap fill patterns located between the second memory cells
neighboring in the second direction.

24. The semiconductor device of claim 23, wherein the first gap fill patterns have substantially the same height as the fourth gap fill patterns, and
wherein the second gap fill patterns have a height less than a height of the third gap fill patterns.
